(19) United States
(12) Patent Application Publication
(10) Pub. No.: US 2026/0282410 A1
(43) Pub. Date: Sep. 17, 2026

(54) SEMICONDUCTOR DEVICE

(71) Applicant: FUJI ELECTRIC CO., LTD., Kanagawa (JP)

(72) Inventors: Takuya YAMADA, Matsumoto-city (JP); Yoshihiro IKURA, Matsumoto-city (JP); Tatsuya NAITO, Matsumoto-city (JP); Hiroki WAKIMOTO, Matsumoto-city (JP); Masaaki FURUKAWA, Matsumoto-city (JP)

(21) Appl. No.: 19/685,082

(22) Filed: May 22, 2026

Related U.S. Application Data
(63) Continuation of application No. PCT/JP2025/017444, filed on May 13, 2025.

(30) Foreign Application Priority Data
Jun. 17, 2024 (JP) 2024-097505

(51) Int. Cl. H10D 12/00; H10D 62/10; H10D 62/60

(52) U.S. Cl. CPC H10D 12/481; H10D 62/102; H10D 62/126; H10D 62/60; H10D 12/415

(57) ABSTRACT

Provided is a semiconductor device comprising a semiconductor substrate having an upper surface and a drift region, trench portions provided inwardly from the upper surface of the semiconductor substrate, mesa portions each being a region sandwiched between two of the trench portions; an emitter electrode, and an interlayer dielectric film with a contact hole formed, wherein the mesa portions include a channel mesa portion having a first conductivity type emitter region and a second conductivity type base region on the upper surface and connected to the emitter electrode by the contact hole, and a hole-extraction mesa portion with no channel formed and connected to the emitter electrode by the contact hole, and a first conductivity type first trench bottom region having a higher concentration than the drift region is provided at a lower end of at least one of the trench portions sandwiching the hole-extraction mesa portion.

The contents of the following patent application(s) are incorporated herein by reference:
NO. 2024-097505 filed in JP on Jun. 17, 2024
NO. PCT/JP2025/017444 filed in WO on May 13, 2025.

### BACKGROUND

### 1. Technical Field

The present invention relates to a semiconductor device.

### 2. Related Art

Conventionally, the semiconductor device provided with a transistor such as an insulated gate bipolar transistor (IGBT) is known (see, for example, Patent Document 1 or 2).

### RELATED ART DOCUMENTS

### Patent Documents

Patent Document 1: International Publication No. 2015/022989
Patent Document 2: Japanese Unexamined Patent Application Publication No. 2019-91892

### BRIEF DESCRIPTION OF THE DRAWINGS

FIG. 1 is a cross-sectional view illustrating an example of the semiconductor device 100 according to one embodiment of the present invention.

FIG. 2 is a cross-sectional view illustrating the semiconductor device 200 according to a comparative example.

FIG. 3 is a cross-sectional view illustrating another example of the semiconductor device 100 according to one embodiment of the present invention.

FIG. 4 is a cross-sectional view illustrating the semiconductor device 300 according to a comparative example.

FIG. 5 is a diagram illustrating turn-on waveforms of the semiconductor device 100 according to an embodiment and the semiconductor device 200 according to a comparative example.

FIG. 6 is a diagram for describing self-charging of the gate trench portion 40.

FIG. 7 is a top view illustrating an example of the active portion 120 of the semiconductor device 100 according to an embodiment.

FIG. 8 is a top view illustrating another example of the active portion 120 of the semiconductor device 100 according to an embodiment.

FIG. 9 is a top view illustrating an example of the termination portion 122 of the semiconductor device 100 according to an embodiment.

FIG. 10 is a top view illustrating another example of the termination portion 122 of the semiconductor device 100 according to an embodiment.

### DESCRIPTION OF EXEMPLARY EMBODIMENTS

Hereinafter, the invention will be described through embodiments of the invention, but the following embodiments do not limit the invention according to claims. In addition, not all of the combinations of features described in the embodiments are essential to the solving means of the invention.

As used herein, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes of an X-axis, a Y-axis, and a Z-axis. The orthogonal coordinate axes merely specify relative positions of components, and do not limit a specific direction. For example, the Z-axis is not limited to indicate the height direction with respect to the ground. Note that a +Z-axis direction and a −Z-axis direction are directions opposite to each other. When the Z-axis direction is described without describing the signs, it means that the direction is parallel to the +Z-axis and the −Z-axis.

In the present specification, orthogonal axes parallel to the upper surface and the lower surface of the semiconductor substrate are referred to as the X-axis and the Y-axis. Further, an axis perpendicular to the upper surface and the lower surface of the semiconductor substrate is referred to as the Z-axis. In the present specification, the direction of the Z-axis may be referred to as the depth direction. Further, in the present specification, a direction parallel to the upper surface and the lower surface of the semiconductor substrate may be referred to as a horizontal direction, including an X-axis direction and a Y-axis direction.

A region from the center in the depth direction of the semiconductor substrate to the upper surface of the semiconductor substrate may be referred to as an upper-surface side. Similarly, the region from the center in the depth direction of the semiconductor substrate to the lower surface of the semiconductor substrate may be referred to as a lower-surface side.

In the present specification, a case where a term such as “same” or “equal” is mentioned may include a case where an error due to a variation in manufacturing or the like is included. The error is, for example, within 10%.

In the present specification, a conductivity type of doping region where doping has been carried out with an impurity is described as a p type or an n type. The n type conductivity type may be the first conductivity type, and the p type conductivity type may be the second conductivity type; however, the corresponding conductivity types may be reversed. In the present specification, the impurity may particularly mean either a donor of the n type or an acceptor of the p type, and may be described as a dopant. In the present specification, doping means introducing the donor or the acceptor into the semiconductor substrate and turning it into a semiconductor presenting a conductivity type of the n type, or a semiconductor presenting conductivity type of the p type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply referred to as the doping concentration.

In the present specification, a description of a p+ type or an n+ type means a higher doping concentration than that of the p type or the n type, and a description of a p− type or an n− type means a lower doping concentration than that of the p type or the n type. Further, in the present specification, when described as p++ type or n++ type, this means that the doping concentration is higher than that of p+ type or n+ type. The unit system of the present specification is the SI unit system unless otherwise specified. The unit of length may be indicated in cm, but various calculations may be performed after conversion into meters (m).

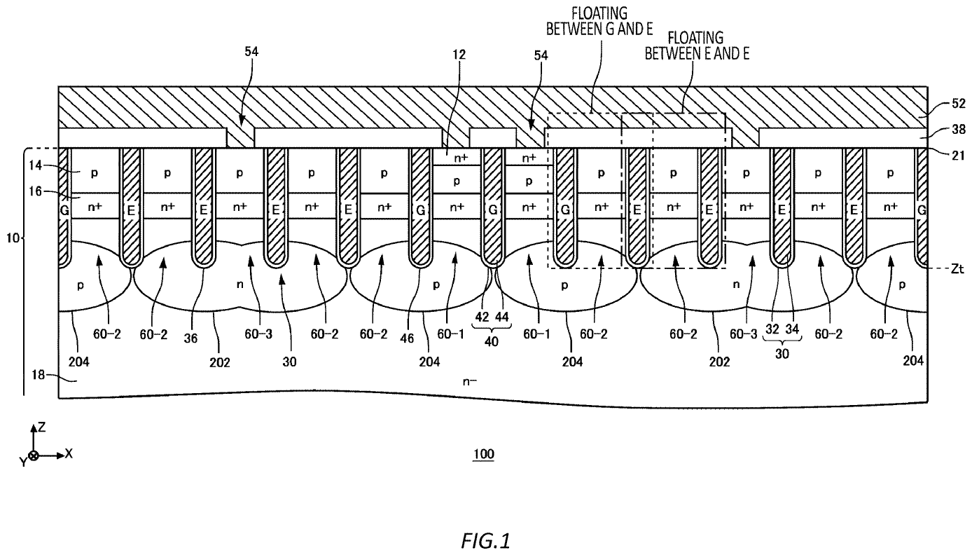

FIG. 1 is a cross-sectional view illustrating an example of the semiconductor device 100 according to one embodiment of the present invention. In the present specification, a case where the semiconductor device 100 is provided with an IGBT (Insulated Gate Bipolar Transistor) as the transistor element will be described as an example. However, the MOSFET (Metal-Oxide-Semiconductor Field-Effect-Transistor) may be provided in the semiconductor device 100. FIG. 1 shows merely some members of the semiconductor device 100, and omits illustrations of some members.

The semiconductor device 100 includes a semiconductor substrate 10, the interlayer dielectric film 38, and the emitter electrode 52. The semiconductor substrate 10 is a substrate that is formed of a semiconductor material. As an example, the semiconductor substrate 10 is a silicon substrate. The semiconductor substrate 10 has the upper surface 21. In FIG. 1, the configuration on the upper surface 21 side of the semiconductor substrate 10 is illustrated, and illustration of the lower-surface side is omitted.

The interlayer dielectric film 38 is provided between the upper surface 21 of the semiconductor substrate 10 and the emitter electrode 52. The interlayer dielectric film 38 is a film including at least one layer of a dielectric film such as silicate glass to which an impurity such as boron or phosphorous is added, a thermal oxide film, and other dielectric films. The contact hole 54 is formed in the interlayer dielectric film 38. The contact hole 54 is the through hole provided to penetrate the interlayer dielectric film 38.

The emitter electrode 52 is provided above the upper surface 21 of the semiconductor substrate 10. The emitter electrode 52 of the present example is provided above the interlayer dielectric film 38. The emitter electrode 52 is connected to the upper surface 21 of the semiconductor substrate 10 via the contact hole 54. The emitter electrode 52 is, as an example, the aluminum-silicon alloy.

In the semiconductor substrate 10, the drift region 18 of an n− type is provided. The drift region 18 may be a remaining region where the semiconductor substrate 10 is not doped. Although not illustrated, on a lower-surface side of the semiconductor substrate 10, a collector region of a second conductivity type is provided in contact with the lower surface. In addition, the collector electrode is provided in contact with the collector region. Between the drift region 18 and the collector region, a field stop layer (FS layer) of the first conductivity type having an impurity concentration higher than that of the drift region 18 may be provided.

The semiconductor substrate 10 has a plurality of trench portions provided from the upper surface 21 of the semiconductor substrate 10 toward the inside. The trench portions may include the gate trench portions 40 and may include the dummy trench portions 30. The gate trench portion 40 is the trench portion to which a gate voltage is applied. The dummy trench portion 30 is connected to the emitter electrode 52 in another cross-section. In FIG. 1 and the subsequent figures, the gate trench portion is indicated as G, and the dummy trench portion is indicated as E. In FIG. 1, hatching is applied to the trench portions.

The trench portions of this example have a plurality of gate trench portions 40 and a plurality of dummy trench portions 30. Each trench portion is arrayed in the array direction (X-axis direction) and extends in an extending direction (Y-axis direction). In FIG. 1, three gate trench portions 40 and four dummy trench portions are periodically arrayed.

A mesa portion 60 is provided between the respective trench portions in the array direction. The mesa portion 60 refers to a region sandwiched between two trench portions inside the semiconductor substrate 10. As an example, an upper end of the mesa portion 60 is the upper surface 21 of the semiconductor substrate 10. The depth position of the lower end of the mesa portion 60 is the same as the depth position of the lower end of the trench portion. The mesa portion 60 of this example is provided extending in the extending direction (the Y-axis direction) along the trench portion, on the upper surface 21 of the semiconductor substrate 10.

In the semiconductor substrate 10 of this example, a plurality of mesa portions 60 are provided. The plurality of mesa portions 60 include the channel mesa portion 60-1, the floating mesa portion 60-2, and the hole-extraction mesa portion 60-3.

The channel mesa portion 60-1 has an emitter region 12 of the n+type and a base region 14 of the p type. The emitter region 12 and the base region 14 are provided in order from the upper surface 21 side of the semiconductor substrate 10. The drift region 18 is provided below the base region 14. In the channel mesa portion 60, the accumulation region 16 of the n+ type may be provided. The accumulation region 16 is arranged between the base region 14 and the drift region 18.

The emitter region 12 is a region of the first conductivity type provided on the upper surface 21 of the semiconductor substrate 10. The emitter region 12 is exposed on the upper surface 21 of the semiconductor substrate 10 and is provided in contact with the gate trench portion 40. The emitter region 12 may be in contact with trench portions on both sides of the channel mesa portion 60-1. The emitter region 12 has a higher doping concentration than the drift region 18.

The base region 14 is a region of the second conductivity type provided between the emitter region 12 and the drift region 18. The base region 14 of this example is provided in contact with the emitter region 12. The base region 14 may be in contact with the trench portions on both sides of the channel mesa portion 60-1.

The accumulation region 16 is a region of the first conductivity type provided between the base region 14 and the drift region 18. The accumulation region 16 is the region of the n+ type having a higher doping concentration than the drift region 18. By providing the accumulation region 16 having a high concentration between the drift region 18 and the base region 14, the carrier injection enhancement effect (IE effect) can be enhanced to reduce a collector-emitter saturation voltage Vce(sat). The accumulation region 16 may be provided so as to cover the entire lower surface of the base region 14 in the channel mesa portion 60.

The gate trench portion 40 includes a gate trench provided in the upper surface 21 of the semiconductor substrate 10, a gate dielectric film 42, and a gate conductive portion 44. The gate dielectric film 42 is provided to cover the inner wall of the gate trench. The gate dielectric film 42 may be formed by oxidizing or nitriding a semiconductor on the inner wall of the gate trench. The gate conductive portion 44 is provided on an inner side relative to the gate dielectric film 42 in the gate trench. That is, the gate dielectric film 42 insulates the gate conductive portion 44 from the semiconductor substrate 10. The gate conductive portion 44 is formed of a conductive material such as polysilicon.

The gate trench portion 40 may be provided to be longer than the base region 14 in the depth direction. The gate conductive portion 44 may be provided longer than the base region 14 in the depth direction. The gate trench portion 40 in the cross-section is covered by the interlayer dielectric film 38 on the upper surface 21 of the semiconductor substrate 10. When a predetermined gate voltage is applied to the gate conductive portion 44, a channel is formed by an electron inversion layer in a surface layer of the base region 14 at a boundary in contact with the gate trench portion 40. Thus, a main current flows between the emitter electrode 52 and the collector electrode (not shown).

The dummy trench portions 30 may have a similar structure to the gate trench portions 40 in the cross-section. That is, the dummy trench portion 30 includes the dummy trench provided on the upper surface 21 of the semiconductor substrate 10, the dummy dielectric film 32, and the dummy conductive portion 34. The dummy conductive portion 34 is electrically connected to the emitter electrode 52 in another cross-section. The dummy dielectric film 32 is provided covering an inner wall of the dummy trench. The dummy conductive portion 34 is provided in the dummy trench, and is provided on an inner side relative to the dummy dielectric film 32. The dummy dielectric film 32 insulates the dummy conductive portion 34 from the semiconductor substrate 10. The dummy conductive portion 34 may be formed of the same material as the gate conductive portion 44. For example, the dummy conductive portion 34 is formed of a conductive material such as polysilicon or the like. The dummy conductive portion 34 may have the same length as the gate conductive portion 44 in the depth direction.

The gate trench portion 40 and the dummy trench portion 30 of this example are covered with the interlayer dielectric film 38 on the upper surface 21 of the semiconductor substrate 10. It is noted that the bottoms of the dummy trench portion 30 and the gate trench portion 40 may be formed in a curved-surface shape (a curved-line shape in the cross-section) convexly downward. In this specification, the depth position of the lower end 46 of the gate trench portion 40 is defined as Zt. The depth position of the lower end 46 of the gate trench portion 40 may be the same as the depth position of the lower end 36 of the dummy trench portion 30.

The channel mesa portion 60-1 is connected to the emitter electrode 52 by the contact hole 54. The channel mesa portion 60-1 may be the mesa portion 60 that is connected to the emitter electrode 52, is provided with the emitter region 12, and in which at least one of the trench portions sandwiching the mesa portion 60 is the gate trench portion 40. The channel mesa portion 60-1 may be sandwiched between two gate trench portions 40.

The floating mesa portion 60-2 has the base region 14 and the accumulation region 16. The floating mesa portion 60-2 may have the emitter region 12 or may not have the emitter region 12. As to the floating mesa portions 60-2 of this example, two floating mesa portions 60-2 are provided continuously adjacent to the channel mesa portion 60-1.

In the floating mesa portion 60-2, the contact hole 54 is not provided thereabove, or a length of the contact hole 54 above in the extending direction (Y-axis direction) is shorter than a length of the contact hole 54 above the channel mesa portion 60-1. In the cross-section illustrated in FIG. 1, the contact hole 54 is not provided above the floating mesa portion 60-2. By providing the floating mesa portion 60-2, holes are more likely to be accumulated when the semiconductor device 100 is turned on.

The hole-extraction mesa portion 60-3 has the base region 14 and the accumulation region 16. The hole-extraction mesa portion 60-3 may have the emitter region 12, or may not have the emitter region 12. In this example, the hole-extraction mesa portion 60-3 is provided adjacent to the floating mesa portion 60-2.

The hole-extraction mesa portion 60-3 is the mesa portion 60 in which a channel is not formed and which is connected to the emitter electrode 52 by the contact hole 54. The hole-extraction mesa portion 60-3 extracts holes injected from the lower-surface side at turn-on of the semiconductor device 100. The hole-extraction mesa portion 60-3 may be the mesa portion 60 that is connected to the emitter electrode 52 and is not provided with the emitter region 12. The hole-extraction mesa portion 60-3 may be the mesa portion that is connected to the emitter electrode 52 and is sandwiched between the dummy trench portions 30. The plurality of mesa portions 60 may include at least one of the channel mesa portion 60-1, the floating mesa portion 60-2, or the hole-extraction mesa portion 60-3, and may include any two thereof.

The semiconductor device 100 of this example includes the first trench bottom region 202 of the first conductivity type provided at the lower end of a trench portion. The first trench bottom region 202 is a region of the n type having a higher concentration than the drift region 18. The first trench bottom region 202 may be provided at the lower end of at least one of the trench portions sandwiching the hole-extraction mesa portion 60-3. In FIG. 1, the first trench bottom region 202 is provided at the lower end 36 of each of two dummy trench portions 30 sandwiching the hole-extraction mesa portion 60-3.

The lower end 36 of the dummy trench portion 30 refers to, in the dummy trench portion 30, the portion farthest from the upper surface 21 of the semiconductor substrate 10. In the example of FIG. 1, the lower end 36 of the dummy trench portion 30 is disposed at the center of the dummy trench portion 30 in the X-axis direction. The lower end 46 of the gate trench portion 40 refers to, in the gate trench portion 40, the portion farthest from the upper surface 21 of the semiconductor substrate 10. In the example of FIG. 1, the lower end 46 of the gate trench portion 40 is disposed at the center of the gate trench portion 40 in the X-axis direction.

When the semiconductor device 100 is turned on, holes flow from the lower surface toward the upper surface 21. Since the channel mesa portion 60-1 has the gate voltage of the gate trench portion 40, holes are less likely to move toward the channel mesa portion 60-1 and are more likely to move toward the hole-extraction mesa portion 60-3. By providing the first trench bottom region 202 in the hole-extraction mesa portion 60-3, holes are less likely to be extracted from the hole-extraction mesa portion 60-3 and are more likely to be accumulated. The displacement current described later is generated by the accumulated holes and the gate voltage is raised (self-charging), so that dI/dt at turn-on can be increased. As a result, the loss generated at turn-on can be significantly reduced.

The first trench bottom region 202 may be provided at the lower end of at least one of the trench portions sandwiching the floating mesa portion 60-2. In FIG. 1, the first trench bottom region 202 is provided at the lower end 36 of one of the dummy trench portions 30 sandwiching the floating mesa portion 60-2. Specifically, the first trench bottom region 202 is provided at the lower end 36 of the dummy trench portion 30 located at the boundary between the floating mesa portion 60-2 and the hole-extraction mesa portion 60-3. By providing the first trench bottom region 202 in the floating mesa portion 60-2, it is possible to suppress holes from moving toward the hole-extraction mesa portion 60-3, and holes are more likely to be accumulated.

At least a part of the first trench bottom region 202 may be provided at a position overlapping the lower end of the trench portion in a plan view, and may be disposed below the lower end in the Z-axis direction. The first trench bottom region 202 may include a portion that does not overlap the lower end in a plan view. The first trench bottom region 202 may include a portion provided above the lower end. The first trench bottom region 202 is in contact with the lower end. In the example of FIG. 1, the first trench bottom region 202 is in contact with the entirety of the curved surface portion including the lower end 36 in the dummy trench portion 30. The first trench bottom region 202 may be formed by injecting an n type dopant in the vicinity of the lower end of the groove structure after forming the groove structure of the trench portion and before forming the conductive portion.

The first trench bottom region 202 is electrically floating with respect to the electrodes such as the emitter electrode 52, the gate conductive portion 44, and the collector electrode. At least one of the region of the p type or the dielectric film is disposed between the first trench bottom region 202 and the electrode. That is, the first trench bottom region 202 and the electrode are not connected only by the region of the n type and a conductive material. The doping concentration of the first trench bottom region 202 may be smaller than the doping concentration of the accumulation region 16. The doping concentration of the first trench bottom region 202 is, as an example, not less than 1×10¹⁵ cm⁻³ and not more than 1×10¹⁷ cm⁻³.

The first trench bottom region 202 is disposed apart from the base region 14 and the accumulation region 16. In this example, the drift region 18 is provided between the first trench bottom region 202 and the accumulation region 16.

The semiconductor device 100 includes one or more first trench bottom regions 202. The semiconductor device 100 may include a plurality of the first trench bottom regions 202. The first trench bottom region 202 may be provided in at least one trench portion, the first trench bottom region 202 may be provided in not less than 10% of the trench portions, the first trench bottom region 202 may be provided in not less than 20% of the trench portions, and the first trench bottom region 202 may be provided in not more than 50% of the trench portions.

When a trench portion provided with the first trench bottom region 202 at the lower end is defined as a corresponding trench portion, each first trench bottom region 202 may or may not extend to below a lower end of a trench portion (in this example, a dummy trench portion 30) disposed adjacent to the corresponding trench portion. Each first trench bottom region 202 may or may not be in contact with the adjacent trench portion.

The mesa portion 60 that is adjacent to the channel mesa portion 60-1 sandwiching therebetween one of the gate trench portions 40, which sandwich the channel mesa portion 60-1, may be a floating mesa portion 60-2. The floating mesa portion 60-2 may be sandwiched between the gate trench portion 40 and the dummy trench portion 30 (floating between G and E in the drawing). Thus, the gate-emitter capacitance Cge is reduced, and the gate-collector capacitance Cgc is increased. As a result, since the temporal change (dVce/dt) of the collector-emitter voltage Vce at turn-on becomes gentle, the gate resistance Rg when the magnitude of dVce/dt is made uniform is reduced, and turn-on loss can be reduced. Further, since dI/dt at turn-on increases, the drop of Vce due to L (circuit inductance)·dI/dt becomes large. This also makes it possible to reduce the turn-on loss.

The mesa portion 60 which is adjacent to the floating mesa portion 60-2 and which is provided on an opposite side to the above-described channel mesa portion 60-1 may be the floating mesa portion 60-2. The floating mesa portion 60-2 may be sandwiched between two dummy trench portions (floating between E and E in the drawing). Thus, the IE effect is enhanced, and Vce(sat) can be reduced.

The semiconductor device 100 may include the second trench bottom region 204 of the second conductivity type provided at the lower end of the trench portion. The second trench bottom region 204 is a region of the p type having a higher concentration than the base region 14. The second trench bottom region 204 may be provided at the lower end of at least one of the trench portions sandwiching the channel mesa portion 60-1. In FIG. 1, the second trench bottom region 204 is provided at the lower end 46 of one of the gate trench portions 40 sandwiching the channel mesa portion 60-1. Specifically, the second trench bottom region 204 is provided at the lower end 46 of the gate trench portion 40 located at the boundary between the channel mesa portion 60-1 and the floating mesa portion 60-2.

By providing the second trench bottom region 204, the electric field at the lower end 46 of the gate trench portion 40 can be relaxed. Therefore, even when the first trench bottom region 202 is formed, the breakdown voltage can be ensured. Further, when the second trench bottom region 204 is provided, the gate potential in the vicinity of the lower end 46 of the gate trench portion 40 becomes less likely to increase. However, since the semiconductor device 100 of the present example causes self-charging of the gate due to accumulation of holes as described above, the gate potential in the vicinity of the lower end 46 can be increased, and Vce(sat) can be reduced.

The second trench bottom region 204 may be provided at the lower end 46 of the gate trench portion 40. The first trench bottom region 202 may be provided at the lower end 36 of the dummy trench portion 30. However, the second trench bottom region 204 may not be provided. The second trench bottom region 204 may not be provided at the lower end 46 of each of the gate trench portions 40 sandwiching the channel mesa portion 60-1.

The second trench bottom region 204, similarly to the first trench bottom region 202, may be formed by injecting a p type dopant in the vicinity of the lower end of the groove structure after forming the groove structure of the trench portion and before forming the conductive portion. However, among three gate trench portions 40 arrayed continuously, the p type dopant may not be injected into the lower end 46 of the gate trench portion 40 at the center.

The second trench bottom region 204 also may not be in contact with the base region 14 and the accumulation region 16. The second trench bottom region 204 may or may not also extend to below the lower end of the trench portion (in this example, the gate trench portion 40 and the dummy trench portion 30) disposed adjacent to the corresponding trench portion. The second trench bottom region 204 and the first trench bottom region 202 may or may not be in contact with each other in the X-axis direction. The second trench bottom region 204 is provided in each of two adjacent mesa portions 60, and the respective second trench bottom regions 204 may not be connected. The doping concentration of the second trench bottom region 204 and the doping concentration of the first trench bottom region 202 may be the same.

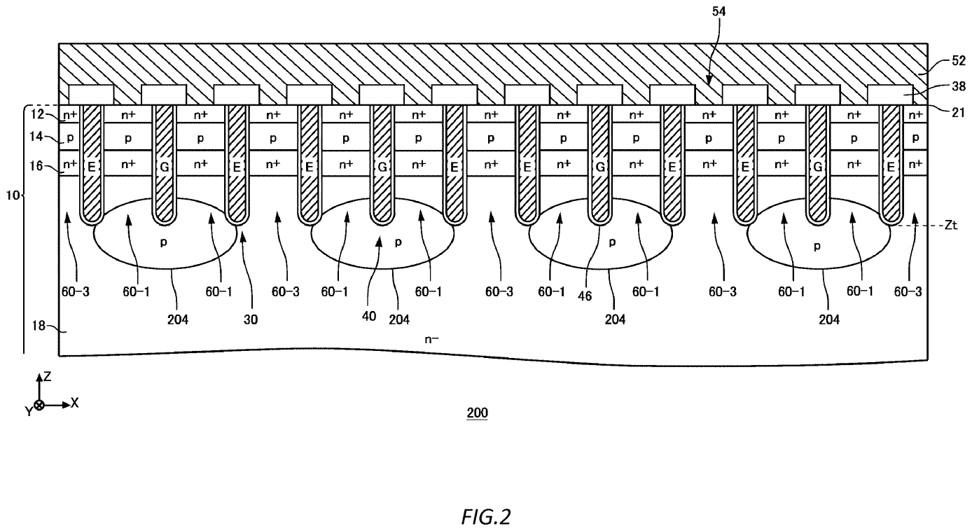

FIG. 2 is the cross-sectional view illustrating the semiconductor device 200 according to the comparative example. Also in FIG. 2, illustration of the lower-surface side of the semiconductor substrate 10 is omitted. Further, description of portions similar to those in FIG. 1 will be omitted. In the semiconductor device 200 of the present example, one gate trench portion 40 and two dummy trench portions 30 are periodically arrayed. Further, all of the mesa portions 60 are connected to the emitter electrode 52, and the floating mesa portion 60-2 is not provided.

The semiconductor device 200 of the present example has the second trench bottom region 204 at the lower end 46 of the gate trench portion 40. In that case, the gate potential in the vicinity of the lower end 46 of the gate trench portion 40 becomes less likely to increase. The semiconductor device 200 of the present example does not have the first trench bottom region 202 and the floating mesa portion 60-2. Therefore, self-charging of the gate due to the accumulation of holes does not occur. Therefore, compared with the semiconductor device 100 according to the embodiment, dI/dt at turn-on becomes slower, and turn-on loss increases. Further, the gate potential in the vicinity of the lower end 46 does not sufficiently increase, and Vce(sat) increases.

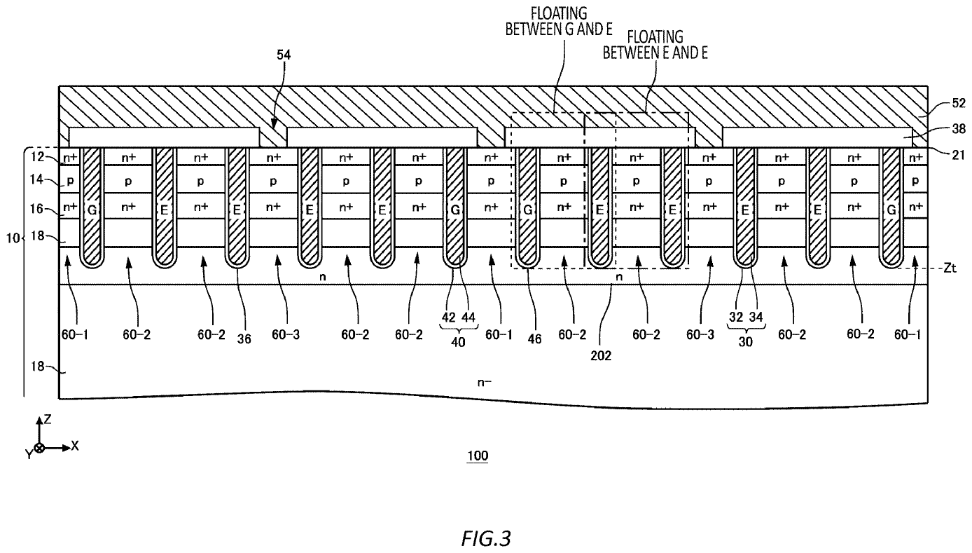

FIG. 3 is the cross-sectional view illustrating another example of the semiconductor device 100 according to one embodiment of the present invention. Also in FIG. 3, illustration of the lower-surface side of the semiconductor substrate 10 is omitted. Further, description of portions similar to those in FIG. 1 is omitted. In the semiconductor device 100 of this example, two gate trench portions 40 and four dummy trench portions 30 are periodically arrayed. In the channel mesa portion 60-1, the floating mesa portion 60-2, and the hole-extraction mesa portion 60-3 of this example, the emitter region 12 is provided.

In the semiconductor device 100, the first trench bottom region 202 may be provided at the lower end of at least one of the trench portions of the channel mesa portion 60-1. In the semiconductor device 100 of this example, the first trench bottom region 202 is provided over the entirety in the width direction of all of the mesa portions 60. Also with such an arrangement of the first trench bottom region 202, effects similar to those in the case of FIG. 1 can be obtained. Further, since the first trench bottom region 202 is provided at the lower ends of all trench portions, uniformity of breakdown voltage is improved. The drift region 18 may be provided between the first trench bottom region 202 and the accumulation region 16.

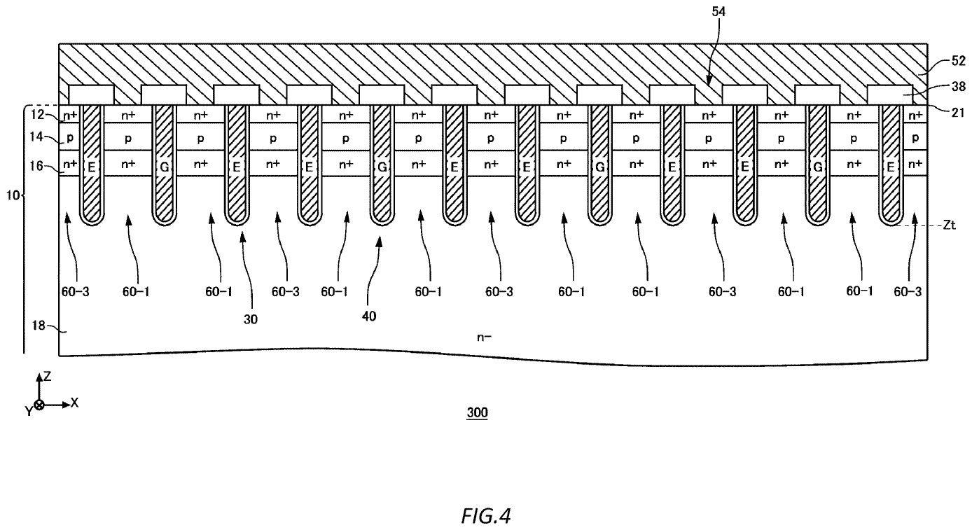

FIG. 4 is the cross-sectional view illustrating the semiconductor device 300 according to the comparative example. The semiconductor device 300 of this example does not include the first trench bottom region 202 and the floating mesa portion 60-2. Therefore, dI/dt at turn-on becomes smaller as compared with the semiconductor device 100 illustrated in FIG. 3, and turn-on loss becomes large.

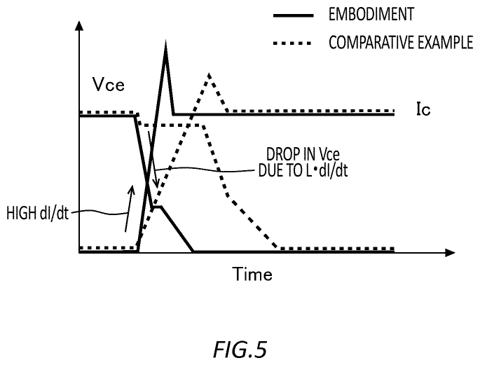

FIG. 5 is a diagram illustrating turn-on waveforms of the semiconductor device 100 according to the embodiment and the semiconductor device 200 according to the comparative example. In the drawing, Vce and the collector current Ic are shown, a solid line in the drawing indicates a waveform of the embodiment, and a dotted line indicates a waveform of the comparative example.

As described above, in the embodiment, since self-charging of the gate due to accumulation of holes occurs, dI/dt becomes large. Further, due to the above-described floating between G and E, Cgc increases, and dI/dt becomes large. Thereby, the drop of Vce due to L·dI/dt becomes large. As a result, the turn-on loss can be significantly reduced.

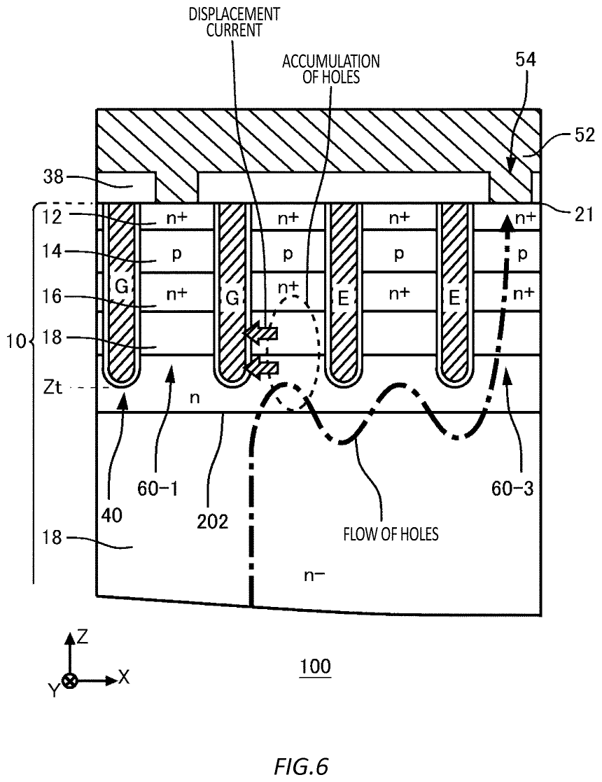

FIG. 6 is a diagram for explaining self-charging of the gate trench portion 40. FIG. 6 is an enlarged view of one channel mesa portion 60-1, two floating mesa portions 60-2, and one hole-extraction mesa portion 60-3 of the semiconductor device 100 in FIG. 3.

An arrow indicated by the one-dot chain line in the drawing indicates a flow of holes at turn-on. Holes moving from the lower surface toward the upper surface 21 avoid the gate trench portion 40 having a high potential, pass below the floating mesa portion 60-2, and flow to the hole-extraction mesa portion 60-3. At this time, the flow of holes is restricted by the floating mesa portion 60-2, the first trench bottom region 202, and the accumulation region 16, and holes are more likely to accumulate. Then, by holes accumulating in the floating mesa portion 60-2 adjacent to the channel mesa portion 60-1, the displacement current directed to the gate trench portion 40 is generated. As a result, the gate trench portion 40 is self-charged, and dI/dt becomes large. In addition, the gate potential in the vicinity of the lower end 46 tends to increase. In the depth direction, at least a part of the first trench bottom region 202 may be located at a position overlapping the gate conductive portion 44.

With reference to FIGS. 1 and 3, the mesa portion 60 sandwiched between two gate trench portions 40 is defined as a first mesa portion. Similarly, the mesa portion 60 sandwiched between the gate trench portion 40 and the dummy trench portion 30 is defined as a second mesa portion, and the mesa portion 60 sandwiched between two dummy trench portions 30 is defined as a third mesa portion. That is, the plurality of mesa portions 60 include the first mesa portion, the second mesa portion, and the third mesa portion.

At least a part of the first mesa portion may be the channel mesa portion 60-1. All of the first mesa portions may be the channel mesa portions 60-1. The first trench bottom region 202 may be provided over the entirety of the width direction (X-axis direction) of at least a part of the first mesa portions. In addition, the first trench bottom region 202 may be provided at the lower end 46 of the gate trench portion 40. However, the first mesa portion may not be provided. In this case, at least a part of the second mesa portions becomes the channel mesa portion 60-1.

At least a part of the second mesa portions may be the floating mesa portion 60-2. All of the second mesa portions may be the floating mesa portions 60-2. The first trench bottom region 202 may be provided over the entirety of the width direction (X-axis direction) of at least a part of the second mesa portions. At least a part of the first mesa portions may be the floating mesa portion 60-2. The second mesa portion provided adjacent to the first mesa portion may be the floating mesa portion 60-2 (floating between G and E). Accordingly, as described above, turn-on loss can be reduced.

At least a part of the third mesa portion may be the floating mesa portion 60-2. All of the third mesa portions may be the floating mesa portions 60-2. The first trench bottom region 202 may be provided over the entirety of the width direction (X-axis direction) of at least a part of the third mesa portions. The third mesa portion provided adjacent to the second mesa portion may be the floating mesa portion 60-2 (floating between E and E). Accordingly, the IE effect is enhanced, and Vce(sat) can be reduced. The third mesa portion may be in contact with the emitter electrode 52 via the contact hole 54. The contact hole may not be provided above the third mesa portion. A part of the third mesa portions may be the hole-extraction mesa portion 60-3.

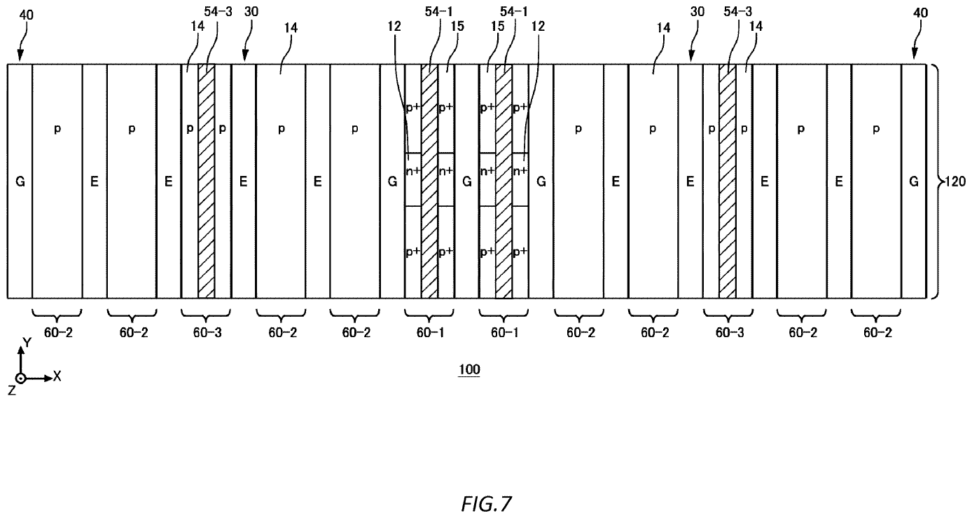

FIG. 7 is a top view illustrating an example of the active portion 120 of the semiconductor device 100 according to the embodiment. The semiconductor device 100 illustrated in FIG. 7 is a top view of the semiconductor device 100 illustrated in FIG. 1. The active portion 120 may be a region in the semiconductor device 100 in which a main current flows, and may be a portion located on an inner side relative to the emitter region 12 that is provided outermost in the channel mesa portion 60-1 in an extending direction (Y-axis direction) of the trench portion described later. FIG. 7 illustrates a part of the active portion 120. Further, the emitter electrode 52 and the interlayer dielectric film 38 are omitted.

The gate trench portion 40 and the dummy trench portion 30 extend in the extending direction. In the channel mesa portion 60-1, the contact region 15 is provided in addition to the emitter region 12. The contact region 15 is a region of the p+ type having a higher doping concentration than the base region 14. In this example, the emitter region 12 and the contact region 15 are alternately provided in the extending direction of the gate trench portion 40.

The contact hole 54 is provided above the channel mesa portion 60-1. In FIG. 7, hatching is applied to the position where the contact hole 54 is provided. The contact hole 54 above the channel mesa portion 60-1 may be provided so as to cross the active portion 120. In the present specification, the contact hole 54 above the channel mesa portion 60-1 may be referred to as the contact hole 54-1.

The base region 14 is exposed on the upper surface of the floating mesa portion 60-2. In the active portion 120, the contact hole 54 is not provided above the floating mesa portion 60-2 of this example. The base region 14 is exposed on the upper surface of a hole-extraction mesa portion 60-3. The contact hole 54 is provided above the hole-extraction mesa portion 60-3. The contact hole 54 above the hole-extraction mesa portion 60-3 may also be provided so as to cross the active portion 120. In the present specification, the contact hole 54 above the hole-extraction mesa portion 60-3 may be referred to as the contact hole 54-3. In the hole-extraction mesa portion 60-3, neither the contact region 15 nor the emitter region 12 is provided. However, the contact region 15 and the emitter region 12 may be provided in the hole-extraction mesa portion 60-3.

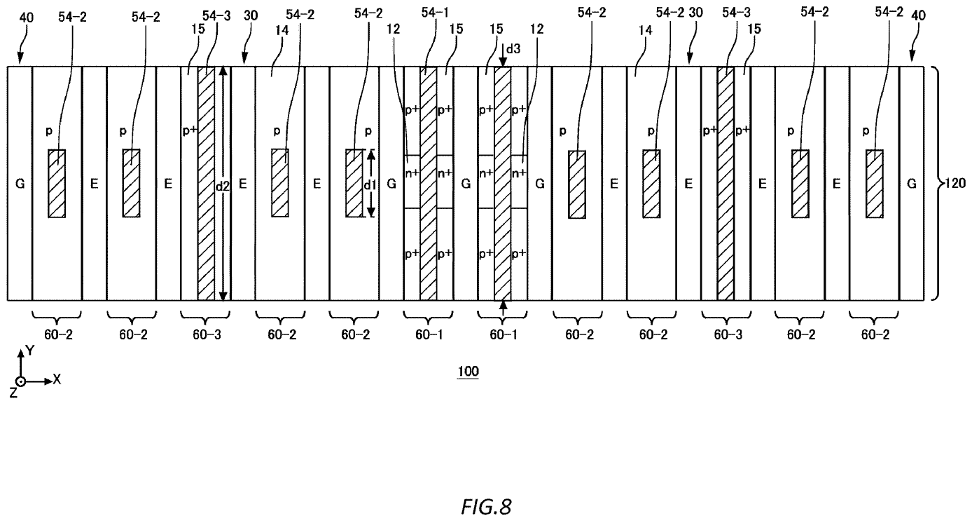

FIG. 8 is a top view illustrating another example of the active portion 120 of the semiconductor device 100 according to the embodiment. The semiconductor device 100 of this example differs from the semiconductor device 100 illustrated in FIG. 7 in configurations of the floating mesa portion 60-2 and the hole-extraction mesa portion 60-3. In the hole-extraction mesa portion 60-3 of this example, the contact region 15 is provided.

A contact hole 54 is provided above the floating mesa portion 60-2 of this example. In the present specification, the contact hole 54 above the floating mesa portion 60-2 may be referred to as the contact hole 54-2. The contact hole 54-2 is the contact hole 54 provided, in an extending direction described later, on an inner side relative to the emitter region 12 that is provided outermost in the channel mesa portion 60-1. That is, the contact hole 54-2 is provided in the active portion. If the contact hole 54-2 is not provided above the floating mesa portion 60-2, dI/dt may become excessively large. By providing the contact hole 54-2 above the floating mesa portion 60-2, the magnitude of dI/dt can be adjusted.

The length d1 of the contact hole 54-2 may be shorter than the length d2 of the contact hole 54-3. The floating mesa portion 60-2 in which the contact hole 54-2 is provided may be the second mesa portion, or may be the third mesa portion.

In at least a part of the third mesa portions not adjacent to the second mesa portion, the contact hole 54 longer than that in the second mesa portion may be provided. The third mesa portion described above in this example is the hole-extraction mesa portion 60-3. The third mesa portion described above may not be the floating mesa portion 60-2. The length d2 of the contact hole 54-3 of the hole-extraction mesa portion 60-3 that is the third mesa portion may be longer than the length d1 of the contact hole 54-2 of the floating mesa portion 60-2 that is the second mesa portion. A case where the length d2 is longer than the length d1 may include a case where the length d1 is zero (the contact hole 54-2 is not provided). The same applies to the relationship between the lengths hereinafter. The length d1 may be not more than half of the length d2, may be not more than 10%, or may be not more than 5%.

The length d1 may be shorter than the length d3 of the contact hole 54-1. The length d1 may be not more than half of the length d3, may be not more than 10%, or may be not more than 5%. The length d2 and the length d3 may be equal. The contact hole 54-1 and the contact hole 54-3 may extend in the Y-axis direction beyond the active portion 120 illustrated in FIGS. 7 and 8. In that case, the end portions of the length d2 and the length d3 are also located on an outer side relative to the active portion 120 illustrated in FIGS. 7 and 8.

Among the plurality of floating mesa portions 60-2, at least one floating mesa portion 60-2 may be provided with the contact hole 54-2, and other floating mesa portions 60-2 may not be provided with the contact hole 54-2. Further, a plurality of contact holes 54-2 may be provided in the same floating mesa portion 60-2 in the extending direction. In that case, the length d1 may be the sum of the lengths of the plurality of contact holes 54-2.

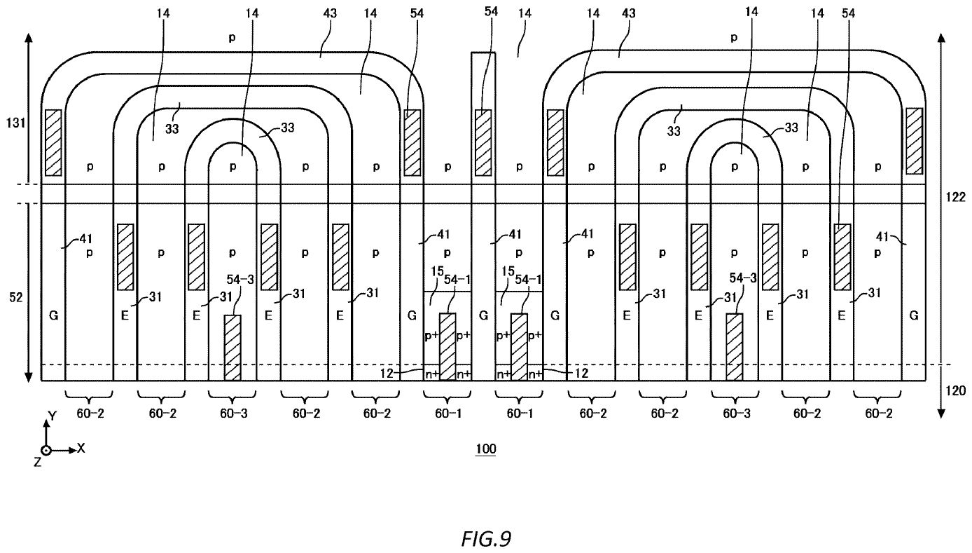

FIG. 9 is a top view illustrating an example of the termination portion 122 of the semiconductor device 100 according to an embodiment. The semiconductor device 100 illustrated in FIG. 9 is a top view of the semiconductor device 100 illustrated in FIG. 7. The termination portion 122 is a portion on an outer side relative to the emitter region 12 that is provided outermost in the channel mesa portion 60-1 in the extending direction (Y-axis direction). In the channel mesa portion 60-1 in FIG. 9, the emitter region 12 is illustrated.

In FIG. 9, the range in which the emitter electrode 52 is provided and the range in which the gate wiring 131 is provided are respectively illustrated. The gate wiring 131 is wiring that transmits a gate voltage to the gate conductive portion 44. In the termination portion 122, the dummy trench portion 30 and the emitter electrode 52 are connected via the contact hole 54. In the termination portion 122, the gate trench portion 40 and the gate wiring 131 are connected via the contact hole 54. However, the dummy trench portion 30 may be connected to the emitter electrode 52 via the contact hole 54 in the active portion 120. In a planar view, the contact hole 54 connected to the dummy trench portion 30 is not adjacent to the contact hole 54 connected to the gate trench portion 40. That is, the contact hole 54 connected to the dummy trench portion 30 and the contact hole 54 connected to the gate trench portion 40 differ in position in the extending direction.

The gate trench portion 40 includes the two extension portions 41 extending in the extending direction, and a connection portion 43 connecting end portions of the two extension portions 41 in a plan view. Similarly, the dummy trench portion 30 includes the two extension portions 31 extending in the extending direction, and a connection portion 33 connecting end portions of the two extension portions 31 in a plan view. By providing the connection portion 43 and the connection portion 33, the mesa portion 60 can be made floating. In the present example, the termination portion 122 is provided with the base region 14, and the base region 14 is connected, for example, to the emitter electrode in another region to be at an emitter potential, but by providing the connection portion 43 and the connection portion 33, the mesa portion 60 can be made floating. That is, the base region 14 surrounded by the connection portion and the extension portion is separated from the base region 14 outside the termination portion 122 by the connection portion and the extension portion.

The connection portion 43 and the connection portion 33 may be provided in the termination portion 122. The extension portion 41 and the extension portion 31 extend from the active portion 120 to the termination portion 122. End portions of the two trench portions (extension portions) sandwiching the floating mesa portion 60-2 may be connected by the connection portion, and may be connected to different connection portions, respectively.

End portions of the two trench portions (extension portions) sandwiching the hole-extraction mesa portion 60-3 may be connected by the connection portion. That is, the base region 14 of the hole-extraction mesa portion 60-3 may be separated from the base region 14 of the floating mesa portion 60-2. Since the base region 14 of the hole-extraction mesa portion 60-3 is connected to the emitter electrode 52, by separating the base region 14 of the hole-extraction mesa portion 60-3 from the base region 14 of the floating mesa portion 60-2, the floating mesa portion 60-2 can be made floating.

The dummy trench portion 30 of this example is provided in a region surrounded by the two extension portions 41 and the connection portion 43. Both the extension portion 31 and the connection portion 33 of the dummy trench portion 30 may be provided in the region surrounded by two extension portions 41 and the connection portion 43. A plurality of dummy trench portions 30 may be provided in the region surrounded by two extension portions 41 and the connection portion 43. Further, in the region surrounded by two extension portions 31 and the connection portion 33 of the dummy trench portion 30, another dummy trench portion 30 may be provided, both the extension portions 31 and the connection portion 33 of the other dummy trench portion 30 may be provided, and a plurality of dummy trench portions 30 may be provided.

The trench portion may include the gate trench portion 40 that is provided between an extension portion connected to one connection portion and an extension portion connected to another connection portion, and that is not connected to the connection portion 43. In the present example, the gate trench portion 40 located at the center in the X-axis direction in FIG. 9 is the gate trench portion 40 that is provided between the extension portion 41 connected to one connection portion 43 and the extension portion 41 connected to another connection portion 43, and that is not connected to the connection portion 43. The gate trench portion 40 described above may be one of the gate trench portions 40 that sandwich the channel mesa portion 60-1.

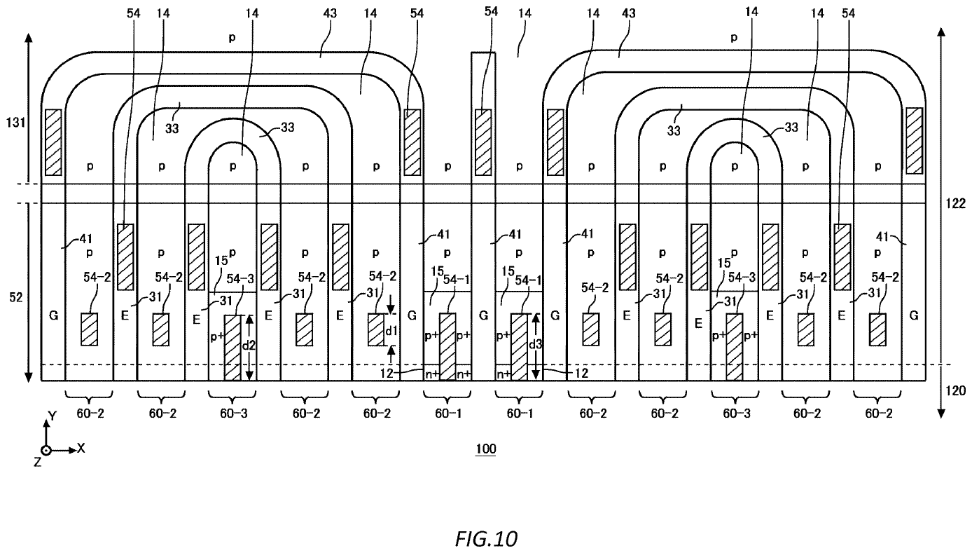

FIG. 10 is a top view illustrating another example of a termination portion 122 of a semiconductor device 100 according to the embodiment. The semiconductor device 100 illustrated in FIG. 10 is a top view of the semiconductor device 100 illustrated in FIG. 8. In the floating mesa portion 60-2 of the semiconductor device 100 of this example, a contact hole 54-2 is provided, in the extending direction, on an outer side relative to the emitter region 12 that is provided outermost in the channel mesa portion 60-1. That is, in the termination portion 122, a contact hole 54-2 is provided above the floating mesa portion 60-2. This makes it possible to adjust the magnitude of dI/dt. In the top view of FIG. 10, the contact hole 54-1 provided in the channel mesa portion 60-1 and the contact hole 54-2 provided in the floating mesa portion 60-2 are provided so as not to be adjacent to the contact hole 54 that is connected to the dummy trench portion 30 or the gate trench portion 40. In other words, the contact holes 54-1, 2 are provided at positions different from the contact hole 54 provided in the dummy trench portion 30 or the gate trench portion 40 in the trench extending direction.

A length d1 of the contact hole 54-2 in the termination portion 122 may be shorter than a length d2 of the contact hole 54-3 and a length d3 of the contact hole 54-1. The contact hole 54-2 of the termination portion 122 may not extend to the active portion 120. Note that, in FIGS. 9 and 10, only one termination portion 122 in the extending direction is illustrated, but the other termination portion may be the same.

The contact hole 54-2 may be provided in both the termination portion 122 and the active portion 120. When the contact hole 54-2 is provided in the same floating mesa portion 60-2, the length d1 of the contact hole 54-2 may be the sum of the length of the contact hole 54-2 of the termination portion 122 and the length of the contact hole 54-2 of the active portion 120.

While the embodiments of the present invention have been described, the technical scope of the invention is not limited to the above described embodiments. It is apparent to persons skilled in the art that various alterations or improvements can be added to the above-described embodiments. For example, when the gate-potential trench also does not contact the emitter region 12, the gate-potential trench can be regarded as the dummy trench portion 30. It is also apparent from the scope of the claims that the embodiments added with such alterations or improvements can be included in the technical scope of the invention.

What is claimed is:

1. A semiconductor device comprising:
a semiconductor substrate which has an upper surface and which is provided with a drift region of a first conductivity type;
a plurality of trench portions which are provided from the upper surface toward an inside of the semiconductor substrate and which extend in an extending direction;
a plurality of mesa portions each being a region sandwiched between two of the trench portions;
an emitter electrode provided above the upper surface of the semiconductor substrate; and
an interlayer dielectric film which is provided between the upper surface of the semiconductor substrate and the emitter electrode and in which a contact hole is formed, wherein
the plurality of mesa portions include:
one or more channel mesa portions each having an emitter region of the first conductivity type provided on the upper surface of the semiconductor substrate and a base region of a second conductivity type provided between the emitter region and the drift region, and each being connected to the emitter electrode by the contact hole; and
one or more hole-extraction mesa portions each including no channel formed therein, and each being connected to the emitter electrode by the contact hole, and wherein
at a lower end of at least one of the trench portions sandwiching each of the one or more hole-extraction mesa portions, a first trench bottom region of the first conductivity type having a higher concentration than the drift region is provided.

2. The semiconductor device according to claim 1, wherein
the plurality of mesa portions include one or more floating mesa portions, in each of which the contact hole is not provided thereabove or in each of which a length of the contact hole above in the extending direction is shorter than a length of the contact hole above the one or more channel mesa portions.

3. A semiconductor device comprising:
a semiconductor substrate which has an upper surface and which is provided with a drift region of a first conductivity type;
a plurality of trench portions which are provided from the upper surface toward an inside of the semiconductor substrate and which extend in an extending direction;
a plurality of mesa portions each being a region sandwiched between two of the trench portions;
an emitter electrode provided above the upper surface of the semiconductor substrate; and
an interlayer dielectric film which is provided between the upper surface of the semiconductor substrate and the emitter electrode and in which a contact hole is formed, wherein
the plurality of mesa portions include:
one or more channel mesa portions each having an emitter region of the first conductivity type provided on the upper surface of the semiconductor substrate and a base region of a second conductivity type provided between the emitter region and the drift region, and each being connected to the emitter electrode by the contact hole; and
one or more floating mesa portions, in each of which the contact hole is not provided above or in each of which a length of the contact hole above in the extending direction is shorter than a length of the contact hole above the one or more channel mesa portions, and wherein
at a lower end of at least one of the trench portions sandwiching each of the one or more floating mesa portions, a first trench bottom region of the first conductivity type having a higher concentration than the drift region is provided.

4. The semiconductor device according to claim 1, wherein
at a lower end of at least one of the trench portions sandwiching each of the one or more channel mesa portions, a second trench bottom region of the second conductivity type having a higher concentration than the base region is provided.

5. The semiconductor device according to claim 1, wherein
the trench portions have a plurality of gate trench portions,
the plurality of mesa portions include one or more first mesa portions each being sandwiched between two of the gate trench portions, and
at least a part of the one or more first mesa portions is the one or more channel mesa portions.

6. The semiconductor device according to claim 2, wherein
the trench portions have a gate trench portion and a dummy trench portion,
the plurality of mesa portions include one or more second mesa portions each being sandwiched between the gate trench portion and the dummy trench portion, and
at least a part of the one or more second mesa portions is the one or more floating mesa portions.

7. The semiconductor device according to claim 2, wherein
the trench portions have a plurality of dummy trench portions,
the plurality of mesa portions include one or more third mesa portions each being sandwiched between two of the dummy trench portions, and
at least a part of the one or more third mesa portions is the one or more floating mesa portions.

8. The semiconductor device according to claim 7, wherein
the trench portions have a gate trench portion,
the plurality of mesa portions include one or more second mesa portions each being sandwiched between the gate trench portion and one of the dummy trench portions, and
the one or more third mesa portions provided adjacent to the one or more second mesa portions are the one or more floating mesa portions.

9. The semiconductor device according to claim 7, wherein
the trench portions have a gate trench portion,
the plurality of mesa portions include one or more second mesa portions each being sandwiched between the gate trench portion and one of the dummy trench portions, and
the contact hole longer than that in the one or more second mesa portions is provided in at least a part of the one or more third mesa portions that is not adjacent to the one or more second mesa portions.

10. The semiconductor device according to claim 2, wherein
in the one or more floating mesa portions, the contact hole is provided on an outer side relative to the emitter region that is provided outermost in the one or more channel mesa portions in the extending direction.

11. The semiconductor device according to claim 2, wherein
in the one or more floating mesa portions, the contact hole is provided on an inner side relative to the emitter region that is provided outermost in the one or more channel mesa portions in the extending direction.

12. The semiconductor device according to claim 1, wherein
the first trench bottom region is provided at a lower end of at least one of the trench portions of the one or more channel mesa portions.

13. The semiconductor device according to claim 12, wherein
the first trench bottom region is provided over an entirety in a width direction of all of the mesa portions.

14. The semiconductor device according to claim 1, wherein
the trench portions have:
a gate trench portion including two extension portions extending in the extending direction and a connection portion connecting end portions of the two extension portions in a plan view; and
a plurality of dummy trench portions provided in a region surrounded by the two extension portions and the connection portion.

15. The semiconductor device according to claim 14, wherein
the trench portions further have
the gate trench portion which is provided between the extension portion connected to one connection portion and the extension portion connected to another connection portion and which is not connected to the connection portion.

16. The semiconductor device according to claim 1, wherein
the lower end of one of the trench portions at which the first trench bottom region is provided is a portion of the one of the trench portions that is farthest from the upper surface of the semiconductor substrate.

17. The semiconductor device according to claim 1, wherein
the one or more hole-extraction mesa portions have the base region of a second conductivity type provided between the upper surface of the semiconductor substrate and the drift region,
the base region of the one or more hole-extraction mesa portions is in contact with one of the trench portions sandwiching the one or more hole-extraction mesa portions,
the base region of the one or more channel mesa portions is in contact with one of the trench portions sandwiching the one or more channel mesa portions, and
the first trench bottom region is separated from the base region of the one or more channel mesa portions and the base region of the one or more hole-extraction mesa portions.

18. The semiconductor device according to claim 2, wherein
the first trench bottom region is provided at least in the one or more floating mesa portions.

19. The semiconductor device according to claim 2, wherein
the plurality of mesa portions include a plurality of floating mesa portions, and
the plurality of floating mesa portions are provided between the one or more channel mesa portions and the one or more hole-extraction mesa portions.

20. The semiconductor device according to claim 2, wherein
at a lower end of at least one of the trench portions sandwiching each of the one or more channel mesa portions, a second trench bottom region of the second conductivity type having a higher concentration than the base region is provided.
